(19) United States
(12) Patent Application Publication
(10) Pub. No.: US 2004/0154829 A1
(43) Pub. Date: Aug. 12, 2004

(54) Low inductance high capacitance power cable for connecting a power supply to an electrical load

(76) Inventor: Forrest L. Sass, Pleasanton, CA (US)

Correspondence Address: Forrest L. Sass, 462 Hamilton Way, Pleasanton, CA, 94566, US

(21) Appl. No.: 10/769,618

(22) Filed: Feb. 2, 2004

Related U.S. Application Data
(60) Provisional application No. 60/443,968, filed on Jan. 31, 2003.

(51) Int. Cl. H05K 1/09

(52) U.S. Cl. 174/257

(57) ABSTRACT

The present invention discloses an electrical cable for connecting a power source to an electrical load wherein the cable has a plurality of conducting members interconnecting the load with the power source and a dielectric insulating material inserted between the conducting members and separated from their inner surfaces in a manner that reduces the magnetic field between the conducting members, reducing inductance and increasing capacitance.

This non-provisional patent application is related to provisional patent application 60/443,968 filed on Jan. 31, 2003.

### CROSS-REFERENCE TO RELATED APPLICATIONS

Not Applicable

### STATEMENT REGARDING FEDERALLY SPONSORED RESEARCH OR DEVELOPMENT

Not Applicable

### REFERENCE TO A MICROFICHE APPENDIX

Not Applicable

### BRIEF DESCRIPTION

The subject of this invention relates to power cables for connecting electrical power supplies to electrical loads. More specifically, the present invention presents a low inductance, high capacitance power cable compared to conventional cables.

### BACKGROUND OF THE INVENTION

Electronic systems and vehicles almost always contain one or more power supplies to convert the Alternating Current (AC) or Direct Current (DC) input power to various lower DC voltages needed by the electronic circuits inside the systems and vehicles. Regardless of the type of current used in a particular system, the power must be delivered to the various components that comprise the system.

In the prior art, a typical connection of power from the power supply to a load such as a circuit board on which multiple Integrated Circuits (ICs) or other power consuming devices are mounted is by a wire harness or cable. One or more circuit boards and peripheral devices have power coupled to them in this manner. In some applications, the cumulative load that must be supplied can range into the hundreds of amps.

In modern complex systems such as computers and/or communications devices a single large multilayer printed circuit board is usually included, a so called mother board, and one or more large ICs including the microprocessor chip and various memory chips are mounted on this motherboard. Use of an ordinary wire harness to couple the power supply to a component on the motherboard has severe limitations. The limitations of conventional wire harnesses include, but are not limited to, significant resistive losses and inductive effects.

As is known in the art, resistive losses are largely determined by the amount of current flowing through the resistance of a wire or conductor. Similarly, inductive effects are largely determined by the rate at which current through a wire changes and the inductance of the wire. Accordingly, the resistive losses and inductive effects are significant in a wire or conductor that delivers power to an IC chip or other component that has a high power demand concurrent with low operating voltage and wide ranging, rapidly changing transient current demand. As a result of the resistive losses and the inductive effects of such power coupling wires or conductors, the combination of a power supply with a traditional wire harness is not able to deliver an accurately regulated, transient free low voltage to a load such as the components on a circuit board requiring high transient currents.

The above disadvantages of using wire harnesses are well known in the art and have resulted in the use of numerous, expensive physical space-consuming capacitors located near the load. An alternative solution, sometimes used in conjunction with the capacitors, is the use of local voltage regulators located in close proximity to devices requiring very tightly controlled voltage tolerances. However, this method suffers from the dual disadvantages of generating heat and consuming power.

The last method discussed just above may be termed distributed power system, in which a power supply produces a single bus voltage output that is distributed around the system. Typically, such a power supply produces a bus voltage of 48 volts. This voltage is preferred because it is low enough to ensure compliance with international safety standards, yet high enough to reduce distribution losses which are proportional to the square of the current. However, other bus voltages, such as 24 volts or 12 volts, are also possible. The distributed power system also includes one or more high density DC to DC converters (that is, converters that have a high power output per cubic volume of space occupied.) These high density DC to DC converters are powered by the bus voltage and are placed in close proximity to the high power demand components they are to power. The reduced distance between the high power demand components and the adjacent power converter significantly reduces the resistive losses and inductive effects in the wires and conductors coupling the power converter to the component

However, distributed power systems are not always desirable. In some applications they are too expensive, take up too much volume or add too much complexity when compared to a single centralized power source. In applications involving the distribution of power from a central rather than distributed power source, it is advantageous to make a cable with minimum resistance, minimum inductance and maximum capacitance in order to help regulate a constant voltage at the load, particularly when the load current changes rapidly. The present invention addresses this need.

It is commonly known that the inductance of a conductor can be significantly reduced by placing a similar conductor carrying and equal and opposite current in close proximity. It is further commonly known that two generally flat conductors which carry equal and opposite current in close proximity and separated by a relatively thin dielectric will exhibit significantly lower inductance than two round wires of equivalent current-carrying capacity separated by a dielectric of the same thickness. Additionally, it is known in the art that the capacitance of a cable is related to the geometry and area of the two adjacent conductors and the type and thickness of the dielectric separating them.

Prior art also teaches that a conductor may be made with a known and fixed amount of inductance and capacitance by using a wire surrounded by a dielectric of fixed thickness which, in turn, is surrounded by an outer conductor or shield. In this scheme the outer conductor or shield is intended to carry the return current of the inner conductor. This is commonly referred to as a coaxial cable, or “coax.”

### BRIEF SUMMARY OF THE INVENTION

The present invention discloses an electrical cable for connecting a power source to an electrical load wherein the cable has a plurality of conducting members interconnecting the load with the power source and a dielectric insulating material inserted between the conducting members and separated from their inner surfaces in a manner that reduces the magnetic field between the conducting members, reducing inductance and increasing capacitance.

More specifically, the present invention discloses an electrical cable for connecting a power source to an electrical load wherein (a) the cable has a plurality of conducting members carrying opposing currents, (b) the cable has two or more distinct magnetic interfaces consisting of adjacent conducting members separated by a relatively thin dielectric material, and (c) any two adjacent conducting members have a “flat” aspect ratio; that is the ratio of width to thickness is ≧5:1.

One object of the present invention is to provide an electrical conductor having a plurality of conducting members, the surfaces of which are separated from each other by a dielectric material for reducing the total inductance and increasing the total capacitance of the cable.

A second object of the present invention is to provide an electrical conductor having a plurality of conducting members formed of a generally rectangularly configured solid conducting material such as copper separated by a dielectric material such as polypropylene such that two or more distinct magnetic fields are generated by alternate conducting layers carrying equal and opposing currents, thereby minimizing the magnetic field contained between the rectangular conducting members.

A third object of the present invention is to provide an electrical conductor having a plurality of interleaved conducting members formed of braided conducting material such as copper wire separated by a dielectric material such that two or more distinct magnetic fields are generated by alternate conducting layers carrying equal and opposing currents, thereby minimizing the magnetic field contained between the rectangular conducting members.

In a first preferred embodiment of the present invention, an electrical conductor for interconnecting a power supply with an electrical load has three or more generally rectangular conducting members formed of an electrical conducting material such as copper and having a cross sectional area in the range of from 2.0 mm by 0.125 mm to 100 mm by 12 mm. Each conducting member is separated from the next conducting member by a dielectric. The conducting members are arranged so that any member carries a current in a direction opposite the two adjacent members.

In a second preferred embodiment of the present invention, an electrical conductor for interconnecting a power supply with an electrical load has a braided conductor typically rated between 1.0 amp and 500 amps placed within a similar braided conductor and insulated therefrom by a dielectric material with a thickness ranging from 0.025 mm to 1.0 mm. The two braided conductors and intervening dielectric are flattened and held in a flattened configuration by an external jacket material surrounding the entire cable thereby advantageously minimizing the separation between the layers.

### BRIEF DESCRIPTION OF THE DRAWINGS

FIG. 1: illustrates a source of power connected to a load with a low inductance power cable which is the subject of the present invention.

FIG. 2: illustrates two types of prior art power cables used to interconnect a power source with a load.

FIG. 3: illustrates a first embodiment of an electrical conductor implemented in accordance with the principles of the present invention.

FIG. 4: illustrates a termination method used to implement connection to the electrical conductor of FIG. 3.

FIG. 5: illustrates a second embodiment of an electrical conductor implemented in accordance with the principles of the present invention.

FIG. 6: illustrates a termination method used to implement connection to the electrical conductor of FIG. 5.

### DETAILED DESCRIPTION OF PREFERRED EMBODIMENTS

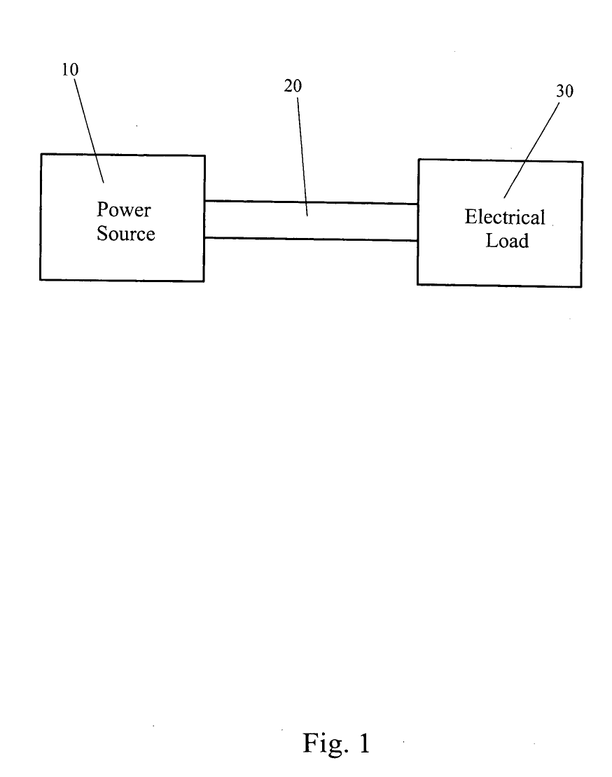

With particular reference to FIG. 1, there is shown an electrical cable 20 in accordance with the principles of the present invention for interconnecting an electrical power supply 10 with an electrical load 30. It is understood that the power supply represents any DC electrical power source. It is further understood that the load would benefit from a low inductance, high capacitance connection to the power source.

As is known in the art, inductance is defined as the flux linkage per unit current. In equation form it is represented as follows:

L=flux linkage/unit current or:

L=NΦ/I

Where:

L=inductance

N=number of turns of wire

Φ=flux

I=current

Since it is also known in the art that Φ=H/ [symbol] , then:

Φ=NI/(λ/Aμ)

Where:

H=magnetomotive force

A=loop area containing magnetic flux

[symbol]

=path reluctance

λ=magnetic path length

μ=permeability of magnetic medium

Solving for inductance L:

L=(N²Aμ)/λ

From this last equation it becomes apparent that inductance is proportional to the area in which the magnetic flux exists and inversely proportional to the magnetic path length. The smaller the area, and/or the longer the magnetic path, the lower the inductance.

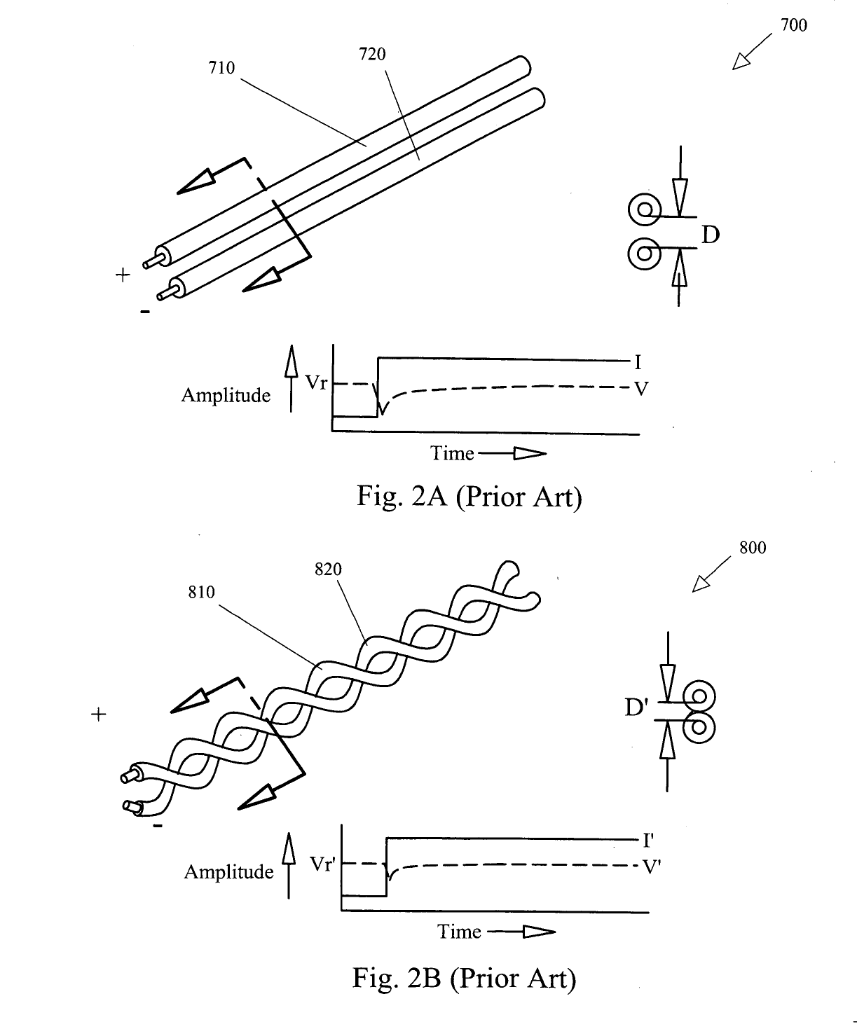

FIG. 2 provides the details of two prior art implementations of power cables interconnecting a power source with a load which adhere to the above formulae. FIG. 2A shows a cable 700 comprised of two conductors 710 and 720. Conductor 710 carries current in the positive direction while conductor 720 carries and equal but opposite current in the negative direction. Since the conductors must be separated by an insulator, a loop is formed by the distance D times the length of the conductors, producing an inductance L per the equations above. Note that the distance D shown in the figure may not be constant. For example, wires in a harness that carry opposite currents may, in fact, be in very close proximity to each other at one location and farther on in the harness be separated by a substantial distance, exacerbating loop dimensions.

FIG. 2A also shows a graph with the X axis representing time, the Y axis representing amplitude. A regulated voltage level V with a specific regulated point Vᵣ is also shown. Any step change in current, for example, step change I in the graph of FIG. 2A, will cause a perturbation in the voltage V proportional to the inductance L. The greater the inductance, the worse the perturbation in both amplitude and duration.

By reducing the loop area, the inductance L may be minimized. If the loop area could be reduced to zero, there would be no inductance. This is the principle behind twisted-pair wire, which is designed to minimize the loop area. The twisting is simply a mechanical means to keep the wires carrying equal and opposite current as closely coupled together as possible. FIG. 2B provides the detail of such a twisted pair of conductors, 800. Note that in the figure the twisted wires 810 and 820 are shown at some distance from each other for clarity. In practice, these wires are in as close a proximity as the mechanical twisting will permit. Conductor 810 carries current in the negative direction while conductor 820 carries an equal but opposite current in the positive direction. The loop area is minimized by mechanically controlling the distance D′ between the conductors by means of twisting.

FIG. 2B also shows a graph with the X axis representing time, the Y axis representing amplitude. A regulated voltage level V′ with a specific regulated point Vᵣ′ is also shown. For the conductor pair configuration of FIG. 2B a step change in current, for example, step change I′ in the graph of FIG. 2B, will still cause a perturbation in the voltage Vᵣ′ proportional to the inductance L. Suppose that the step current change I′ is of the same magnitude as that for FIG. 2A above, the voltage perturbation Vr′ is less than that for the non-twisted conductor pair 700 in both amplitude and duration.

From the equations above it can be seen that a further way to reduce the inductance L in a set of conductors is to increase the magnetic path length λ. By so doing the disadvantages of the prior art may be significantly reduced.

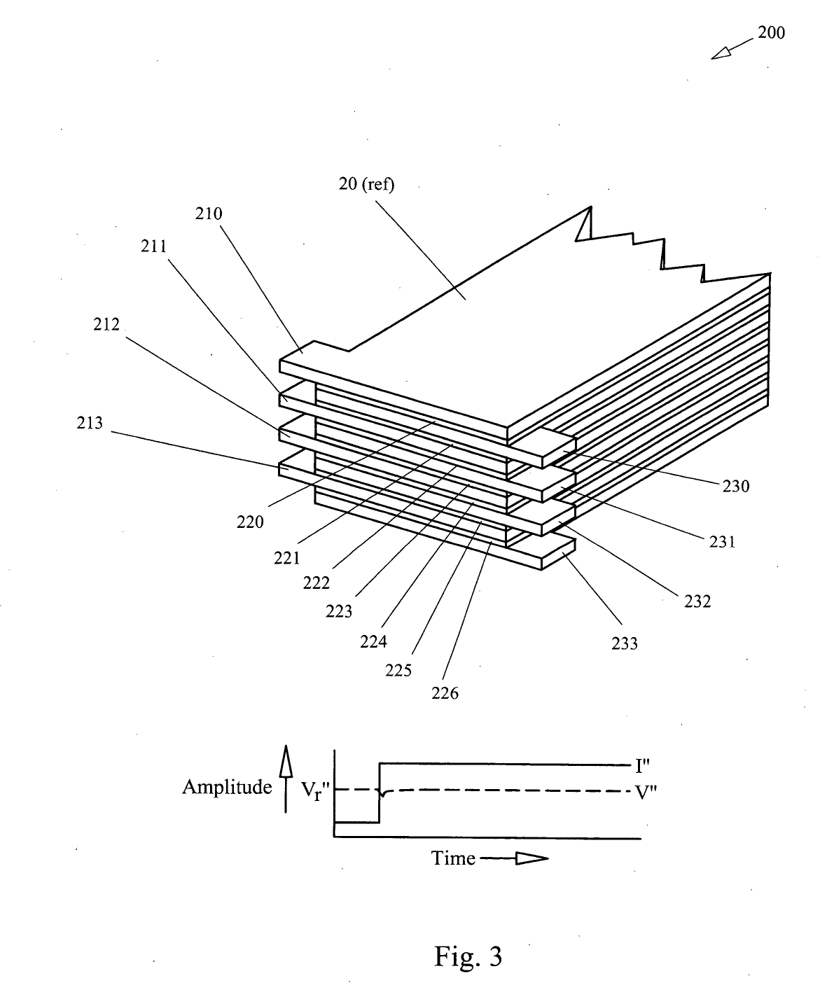

FIG. 3 shows a first embodiment 200 of the electrical cable of the present invention. While FIG. 3 shows eight conducting members (that is four pairs of conductors carrying equal and opposite currents), it will be recognized that this is illustrative only, and more or fewer layers could be used without departing from the spirit of the invention, thus the use of eight conducting members should not be read as a limitation on the scope of the invention. In practice there can be any number of conducting members from as few as two to as many as over one hundred so long as there are two or more interfaces of members carrying substantially equal and opposite currents. Electrical cable 200 exhibits very low inductance and high capacitance for use in interconnecting a power source with an electrical load. In general, although not limited thereto, it is used in an exemplary embodiment with direct current (DC) loads that require a very highly regulated voltage on the order of plus or minus one percent or current slew rates exceeding 10 Amps per microsecond. It will be recognized, however, that the present invention could be used with alternating current (AC) as well.

The electrical cable 200 has conducting members 210, 211, 212 and 213 each formed as a generally rectangular member of an electrical conducting material such as copper and which conducts current in one direction. In addition, conducting members 230, 231, 232 and 233 are each formed as a generally rectangular member of an electrical conducting material such as copper and which conducts current in a direction opposite the current in members 210, 211, 212 and 213. The conducting members are arranged in a special relationship to one another set forth by the present invention such that conducting members 210, 211, 212 and 213 are alternated with conducting members 230, 231, 232 and 233. Between adjacent conducting members is dielectric material 220, 221, 222, 223, 224, 225 and 226 of substantially the same dimensions as the conducting members that serves to insulate one conducting member from another. The dimensions of the conducting members and associated insulating material is such that the width is at least five times greater than the height. This ratio is used to create a high level of magnetic coupling between the conducting members carrying opposite currents. While ratios of width to height less than 5:1 could be used without departing from the sprit of the invention, a sub-optimal magnetic field coupling may result, decreasing the effectiveness of the invention.

It will be recognized that conducting material other than copper could be used without departing from the spirit of the invention, thus the use of copper should not be read as a limitation the scope of the invention. By way of example, the conducting material could be aluminum, steel, or gold in either solid, plated or braided configurations.

Also shown in FIG. 3 is a graph with the X axis representing time and the Y axis representing amplitude. Also shown is a regulated voltage level V with a specific regulated point Vᵣ″. For this configuration a step change in current, for example, step change I″ of the same magnitude as for step change I in the graph of FIG. 2A, will still cause a perturbation in the voltage Vᵣ″ proportional to the inductance L.

However, the result of constructing a power cable 200 in the manner described in detail above is that for a step current change I, similar in value to that for FIG. 2A, the resultant voltage perturbation Vᵣ″ is significantly reduced. As detailed further below, inductance L using the method of the present invention can be reduced by greater than two orders of magnitude, capacitance C by over three orders of magnitude and resistance R by more than one order of magnitude.

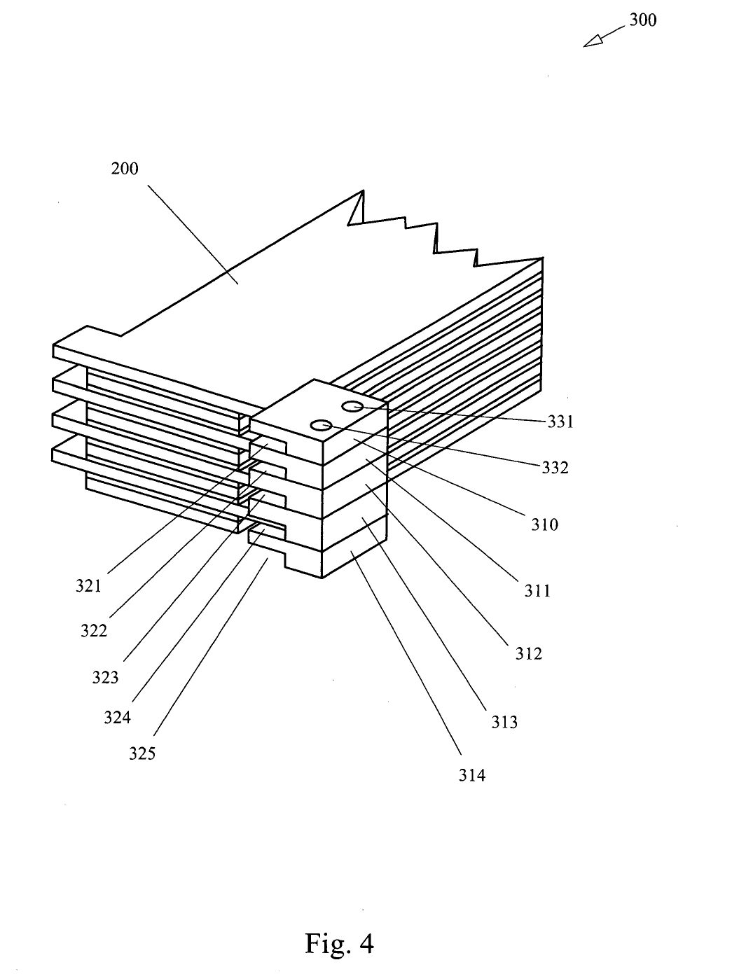

FIG. 4 presents one method 300 for terminating electrical cable 200. Alternate conducting members are positioned slightly offset from one layer to the next so that all conducting members carrying current in one direction extend clear of the conducting member stack on one side. In a similar manner, all conducting members carrying current in the opposite direction extend clear of the opposite side of the conducting member stack. Plates 310, 311, 312, 313 and 314, each formed as a generally rectangular tab of an electrical conducting material such as copper alloy with recessed areas 321, 322, 323, 324 and 325 and mounting holes 331 and 332 are positioned as shown. A machine screw (not shown) placed in each hole 331 and 332 and tightened would lock the plates onto the conducting members on one side of the conducting member stack providing a mechanical captive force as well as excellent electrical connection. A similar array of plates on the opposite side of the conducting member stack (not shown) would serve to provide electrical connection and captive force to the remaining conducting members. Note that the purpose of the recessed areas 312, 322, 323, 324 and 325 are to provide just enough clearance to allow each of the conducting members to be contacted by its associated plate so as to be clamped securely without deforming either the insulating dielectric or interleaved conducting members.

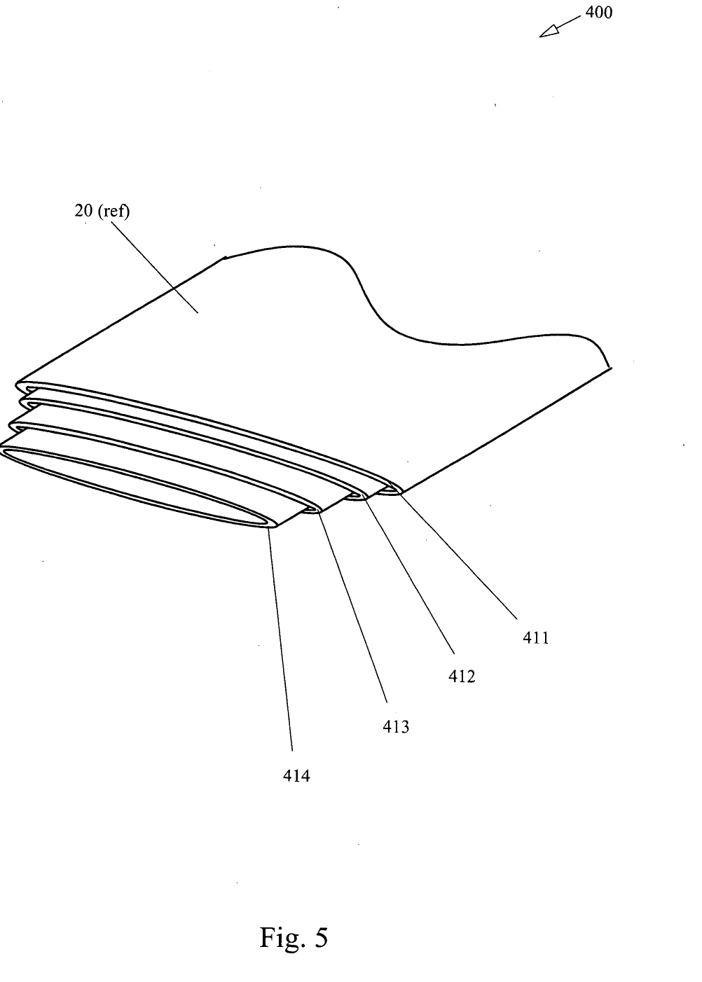

FIG. 5 presents a second embodiment 400 of the electrical cable of the present invention. The electrical cable 400 consists of conducting members 412 and 414 which are made of a tubular conductive mesh of wires commonly called “braid.” The insulating member 413 consists of a tubular dielectric material such as polypropylene. The dimensions are chosen so that conducting member 414 fits within insulating member 413, insulating member 413 fits within conducting member 412, conducting member 412 fits within insulating member 411. As will be recognized, a plurality of conducting and insulating members could be so concentrically arranged, thus the use of two conducting members in the exemplary embodiment should not be read as a limitation on the scope of the invention. As with the first preferred embodiment described above, the width to height ration must be greater than 5:1 to achieve predicted performance.

An insulating over-wrap 411 protects the inner conducting and insulating members. In this instantiation conducting member 414 is presumed to carry current in one direction while conducting member 412 carries current in the opposite direction. In so doing the electrical cable 400 operates in accordance with the principles of the present invention by minimizing inductance and creating high capacitance.

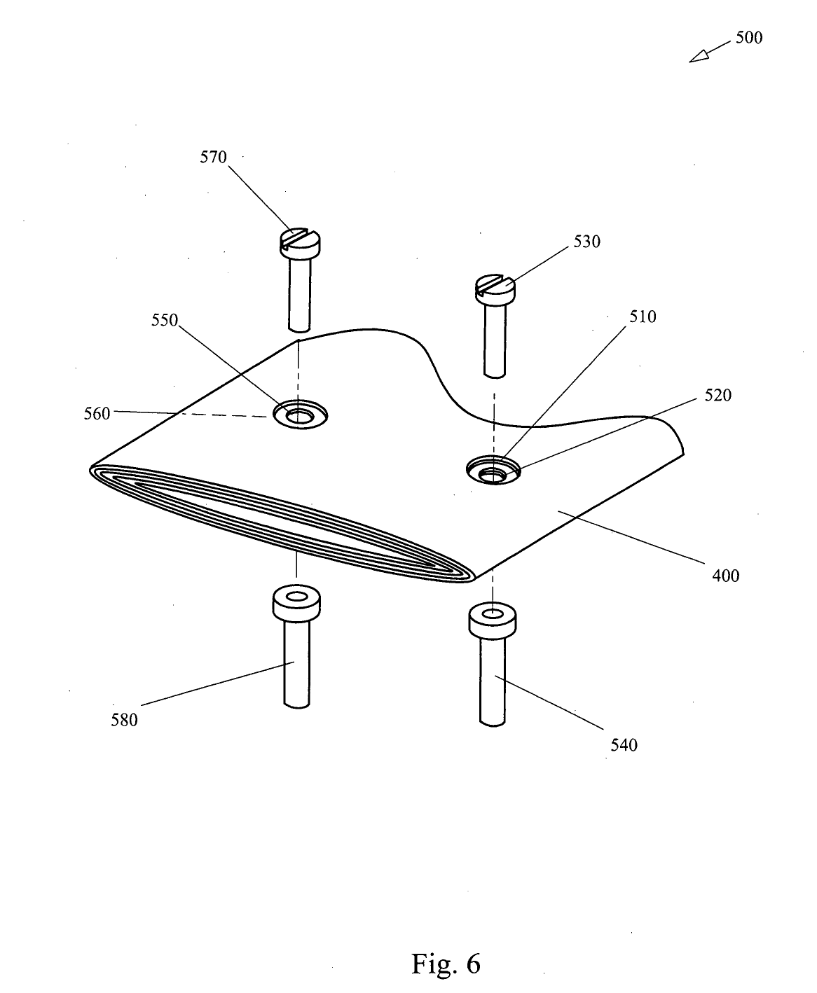

FIG. 6 presents one method 500 for terminating electrical cable 400. For the discussion of this figure it is assumed that the conducting members and insulating materials of FIG. 4 are used, thus the numerical callouts will be the same. A large hole 510 with a diameter significantly larger than screw 530 is punched in the insulating material 411 and conducting member 412. A hole generally the same size as screw 530 and concentric with hole 510 is punched in insulating material 413 and conducting member 414. Screw 530 is positioned such that when tightened against pin 540 no contact is made with conducting member 412 but electrical connection and captive force is provided for conducting member 414. In a similar manner, a large hole 560 (not shown) with a diameter significantly larger than screw 570 is punched in insulating material 413 and conducting member 414. A hole generally the same size as screw 570 and concentric with hole 550 is punched in insulating material 411 and conducting member 412. Screw 570 is positioned such that when tightened against pin 580 no contact is made with conducting member 414 but electrical connection and captive force is provided for conducting member 412.

Both of the construction methods of FIGS. 3 and 5 perform according to the equations below.

Resistance per foot:

R≈1.065^{E+4}/circular mils

Inductance L:

Lₙ=(l·g·μ₀·2.54)/w

Where:

Lₙ=inductance of n^{th} interface

l=length in feet

g=gap in inches

w=width in inches

μ₀=4π×10⁻⁹

2.54=conversion constant (metric to inches) And total inductance for a particular conductor instance:

Lₜₒₜₐₗ₌1/(1/L₁+1/L₂+1/L₃ . . . 1/Lₙ)

Capacitance C:

Cₙ=(ε [symbol] ·A·μ₀·0.0254)/d

Where:

Cₙ=capacitance of the n^{th} interface

ε [symbol] =8.854×10⁻¹² F/M

A=area in square inches

0.0254=conversion constant (metric to inches)

d=gap in inches

Cₜₒₜₐₗ=Σ(C₁+C_{2+C}₃ . . . Cₙ)

Specific performance data based upon calculated values for each of the construction methods of the present invention and an ordinary wire pair using various sizes of wire are shown in Tables 1 through 4 below.

Looking first at Table 1, a 25 Amp capacity comparison is shown. An ordinary wire pair constructed of 0.23 diameter copper wire is compared to a four layer flat conductor construction, for example, that shown in FIG. 3, and a concentric conductor, for example, that shown in FIG. 5. The flat conductor is made of copper that has a cross section measuring 0.011 by 0.5 inches, with three inter layer interfaces separated by 0.005 inch insulation. The concentric conductor is also made of copper measuring 0.012 by 0.49 with a 0.005 insulating interface. As can be seen, both the flat and concentric conductors demonstrate significantly lower resistance and inductance and significantly increased capacitance.

TABLE 1

| | | | Flat | |
|---|---|---|---|---|
| 25 amp | | Wire Pair | Conductor | Concentric Conductor |
| R | micro-ohms/ft | 1860 | 190 | 178 |
| L | pico-henries/ft | 514000 | 1920 | 1950 |
| C | picofarads/ft | 3 | 540 | 529 |

Referring now to Table 2, a 50 Amp capacity comparison is shown. An ordinary wire pair constructed of 0.149 diameter copper wire is compared to a four layer flat conductor construction, for example, that shown in FIG. 3, and a concentric conductor, for example, that shown in FIG. 5. The flat conductor is made of copper that has a cross section measuring 0.011 by 1.0 inches, with three inter layer interfaces separated by 0.005 inch insulation. The concentric conductor is also made of copper measuring 0.006 by 1.17 inches with a 0.005 insulating interface. As with the cables compared in Table 1 above, both the flat and concentric conductors demonstrate significantly lower resistance and inductance and significantly increased capacitance.

TABLE 2

| | | | Flat | |
|---|---|---|---|---|
| 50 amp | | Wire Pair | Conductor | Concentric Conductor |
| R | micro-ohms/ft | 730 | 95 | 149 |
| L | pico-henries/ft | 383000 | 958 | 818 |
| C | picofarads/ft | 3 | 1080 | 1260 |

Referring now to Table 3 and 4, 100 Amp and 300 Amp capacity comparisons are shown. For Table 3, the ordinary wire pair constructed of 0.409 diameter copper wire is compared to a four layer flat conductor construction, for example, that shown in FIG. 3, and a concentric conductor, for example, that shown in FIG. 5. The flat conductor is made of copper that has a cross section measuring 0.005 by 3.5 inches, with three inter layer interfaces separated by 0.005 inch insulation. The concentric conductor is also made of copper measuring 0.006 by 3.53 inches with a 0.005 insulating interface.

TABLE 3

| | | Wire | Flat | |
|---|---|---|---|---|
| 100 amp | | Pair | Conductor | Concentric Conductor |
| R | micro-ohms/ft | 300 | 50 | 50 |
| L | pico-henries/ft | 383000 | 274 | 271 |
| C | picofarads/ft | 3 | 3780 | 3810 |

For the case shown in Table 4, the ordinary wire pair constructed of 0.814 diameter copper wire is compared to a four layer flat conductor construction, for example, that shown in FIG. 3, and a concentric conductor, for example, that shown in FIG. 5. The flat conductor is made of copper that has a cross section measuring 0.02 by 3.5 inches, with three inter layer interfaces separated by 0.01 inch insulation. The concentric conductor is also made of copper measuring 0.025 by 3.0 inches with a 0.01 insulating interface.

TABLE 4

| | | | | Concentric |
|---|---|---|---|---|
| 300 amp | | Wire Pair | Flat Conductor | Conductor |
| R | micro-ohms/ft | 59 | 15 | 14 |
| L | pico-henries/ft | 383000 | 365 | 638 |
| C | picofarads/ft | 3 | 2830 | 1620 |

As with the cables compared in Table 2 above, both the flat and concentric conductors for the cases presented in Tables 3 and 4 demonstrate significantly lower resistance and inductance and significantly increased capacitance. Further, it should be stated that either of the construction methods of the present invention are far more economical than the prior art solutions. This is so due to the increasing cost of the copper required to construct an ordinary cable. For example, a 0.5 inch diameter copper wire will be very expensive when compared to four layers of conducting material measuring 0.005 by 3.5 inches.

A first advantage of the method of the present invention is increased transient current performance over prior art examples. By providing an increased magnetic path and decreased conductor separation at the conductor/insulator interface, resistance and inductance are significantly reduced and capacitance significantly increased. The result is a much improved level of voltage stability at the load.

A second advantage of the present invention is the reduction in the need for discrete bypass capacitors at the load. Since the capacitance of the cable has been significantly increased, the voltage transients at the load are far less, thus the need for the discrete capacitors is reduced or eliminated.

A third advantage of the present invention is economic. The economic advantage occurs both because of less expensive material and because of the reduction or elimination of the bypass capacitors mentioned above.

A fourth advantage of the present invention is that it may be used with both AC and DC currents of high magnitude. Using the method of the present invention thus helps to simplify system design by requiring only one type of power feed methodology.

What is claimed is:

1. An electrical cable providing low inductance and high capacitance for interconnecting a power source with an electrical load, comprising:
a first conducting member;
at least a second conducting member;
a first insulating member, and;
at least two interfaces where said first conducting member is placed in close proximity to said
at least second conducting member, said first conducting member and said at least second conducting member separated from each other by said first insulating layer such that the current present in said first conducting member is substantially equal to but opposed by the current in said at least second conducting member.

2. An electrical cable according to claim 1 wherein the ratio of the width of the conducting members and insulating members to the height of the said conducting members and said insulating members is at least five to one.

3. An electrical cable providing low inductance and high capacitance for interconnecting a power source with an electrical load and having a plurality of conducting members carrying opposing currents, comprising:
a first conducting member;
at least a second conducting member, and;
a first insulating member, wherein
said first conducting member, said at least second conducting member and said first insulating member form two or more distinct magnetic interfaces such that the substantially equal but opposing currents in said first conducting member and said at least second conducting member minimizes the voltage destabilizing effects at said electrical load of step current changes in said conducting members.

4. An electrical cable according to claim 3, comprising:
a first conducting member;
at least a second conducting member, and;
a first insulating member, wherein said first conducting member, said at least a second conducting member and said at least a first insulating member are formed of a generally rectangularly configured solid conducting material separated by a dielectric material.

5. An electrical cable according to claim 3, comprising:
a first conducting member;
at least a second conducting member, and;
a first insulating member, wherein said first conducting member, said at least a second conducting member and said at least a first insulating member are formed of a generally concentricly configured braided conducting material separated by a dielectric material.

6. The electrical cable according to claim 4 wherein the first conducting member is copper having a minimum cross sectional area of 2.0 mm by 0.125 mm, the at least a second conducting member is copper having a minimum cross sectional area of 2.0 mm by 0.125 mm, said first conducting member and said at least a second conducting member separated by a dielectric member having a maximum thickness of 1.0 mm.

7. The electrical cable according to claim 5 wherein the first conducting member is copper braid having a minimum cross sectional area of 2.0 mm by 0.125 mm, the at least a second conducting member is copper braid having a minimum cross sectional area of 2.0 mm by 0.125 mm, said first conducting member and said at least a second conducting member separated by a dielectric member having a maximum thickness of 1.0 mm.
